(19) United States
(12) Patent Application Publication
(10) Pub. No.: US 2019/0339013 A1
(43) Pub. Date: Nov. 7, 2019

(54) HEAT TRANSFER APPARATUS

(71) Applicant: Deutsches Zentrum fuer Luft- und Raumfahrt e.V., Koeln (DE)

(72) Inventors: Christian Haefele, Stuttgart (DE); Tobias Weiler, Lichtenwald (DE); Frank Rinderknecht, Boeblingen (DE); Thomas Braig, Allmendingen (DE)

(21) Appl. No.: 16/418,001

(22) Filed: May 21, 2019

Related U.S. Application Data
(63) Continuation of application No. PCT/EP2017/080373, filed on Nov. 24, 2017.

(30) Foreign Application Priority Data
Dec. 6, 2016 (DE) 20 2016 106 782.0

(51) Int. Cl. F28D 7/10; H01L 35/32; H01L 35/30; F01N 5/02; F28D 20/02; F28D 21/00; F28D 7/16; F28F 1/02

(52) U.S. Cl. CPC F28D 7/10; H01L 35/32; H01L 35/30; F01N 5/025; F28D 2020/0013; F28D 21/0003; F28D 7/1684; F28F 1/022; F01N 2410/02; F28D 20/021

(57) ABSTRACT

A heat transfer apparatus is provided, comprising a fluid-tight first housing and at least one fluid-tight second housing, wherein the at least one second housing is arranged in the first housing, a fluid-tight third housing is arranged in the at least one second housing, a first medium flow is guided between the first housing and the at least one second housing, a second medium flow is guided in the third housing, the heat transfer apparatus comprises a heat storage device with a heat-conducting medium, the heat storage device is arranged between the at least one second housing and the third housing, and wherein the heat storage device is in thermal contact with the at least one second housing and the third housing.

This application is a continuation of international application number PCT/EP 2017/080373 filed on Nov. 24, 2017 and claims the benefit of

German application number 20 2016 106 782.0 filed on Dec. 6, 2016, which are incorporated herein by reference in their entirety and for all purposes.

### BACKGROUND OF THE INVENTION

The invention relates to a heat transfer apparatus, comprising a fluid-tight first housing and at least one fluid-tight second housing, wherein the at least one second housing is arranged in the first housing, a fluid-tight third housing is arranged in the at least one second housing, a first medium flow is guided between the first housing and the at least one second housing, and wherein a second medium flow is guided in the third housing.

A thermoelectric generator apparatus is known from DE 10 2010 042 603 A1. The thermoelectric generator apparatus comprises a fluid-tight first housing, at least one fluid-tight second housing which is arranged in the first housing, wherein a first medium flow is guided between the first housing and the at least one second housing, a fluid-tight third housing which is arranged in the at least one second housing, wherein a second medium flow is guided in the third housing, and at least one thermoelectric module which is arranged between the at least one second housing and the third housing. The at least one thermoelectric module is with a side in thermal contact with the second housing and with a second side in thermal contact with the third housing.

A thermoelectric generator apparatus is known from DE 10 2013 112 911 A1, comprising a housing and at least one combination with the components first cold heat exchanger, second cold heat exchanger, first thermoelectric layer, second thermoelectric layer, and hot heat exchanger, wherein in the at least one combination the hot heat exchanger is arranged between the first thermoelectric layer and the second thermoelectric layer, the first cold heat exchanger is arranged on the first thermoelectric layer and the second cold heat exchanger on the second thermoelectric layer, and wherein the at least one combination is positioned in the housing. Provision is made in the thermoelectric generator apparatus for a first inner side of a first wall of the housing to be in direct areal mechanical contact with the first cold heat exchanger of the at least one combination or the first wall forms a walling of the first cold heat exchanger, for a second inner side of a second wall of the housing, which second inner side is opposite the first inner side, to be in direct areal mechanical contact with the second cold heat exchanger of the at least one combination or of a further combination or forms a walling of the second cold heat exchanger, and for the housing to provide a contact pressure by positive locking at least at an operating point or operating point range of the thermoelectric generator apparatus, which contact pressure braces the components of the at least one combination against each other and clamps the same in the housing.

A heat exchanger with at least one heat transfer element is known from DE 10 2013 105 294 A1. The at least one heat transfer element is produced of a metallic material and heat is transferable by the at least one heat transfer element. An electrical insulating layer through which a heat flow can be conducted is arranged on the at least one heat transfer element by substance-to-substance bond.

A thermoelectric apparatus is known from DE 10 2013 100 396 A1, comprising a thermoelectric module device with a cold side and a hot side, and a latent heat storage device which is arranged on the hot side of the thermoelectric module device, wherein the latent heat storage device has at least one housing with a receiving space for a phase change medium, the at least one housing has a first walling and an opposite second walling, the first walling is in contact with the hot side of the thermoelectric module device and a supporting structure with at least one support element is arranged between the first walling and the second walling, which support element is supported on the first walling and the second walling.

A thermoelectric apparatus is known from DE 10 2011 114 102 A1, which is adapted and configured for arrangement in an exhaust gas system for temporarily receiving and discharging a hot flowing exhaust gas flow from a combustion engine for propulsion of a motor vehicle.

### SUMMARY OF THE INVENTION

In accordance with an embodiment of the invention, it is to provide a heat transfer apparatus which is designed in a constructively simple manner and in which the heat transfer between the components is improved in the operation thereof.

In accordance with an embodiment of the invention, the heat transfer apparatus stated at the outset comprises a heat storage device with a heat-conducting medium, wherein the heat storage device is arranged between the at least one second housing and the third housing, and wherein the heat storage device is in thermal contact with the at least one second housing and the third housing.

The second medium flow is, e.g., a hot medium flow, for example an exhaust gas flow of a combustion engine. The first medium flow is then a cold medium flow with, e.g., cooling water as the cooling medium.

The first medium flow and the second medium flow may be guided in a simple manner without contact with each other, the constructive expenditure for preventing contact being minimized.

Further, a cooling of the at least one second housing may be achieved by the latter being flowed around with the first medium flow.

As a result of the heat storage device, fluctuations in a heat emission of the hot medium flow may be at least partially compensated. Fluctuations in the heat emission to other components like, for example, to a thermoelectric module are thereby reduced. The heat storage device may store heat in times of high heat emission by the hot medium flow and emit the stored heat in times of low heat emission by the hot medium flow. Fluctuations in a heat flow, for example at the thermoelectric module, are hereby reduced. The efficiency of the thermoelectric module is hereby increased.

The heat-conducting medium is or comprises, in particular, a phase change medium. As a result of the phase change medium, heat may be stored in a simple manner and the stored heat again released. The heat storage device may thereby be realized in a technically simple manner.

It is favorable if a plurality of parallel channels separated in a fluid-tight manner are formed in the first housing. A great amount of heat may thereby be transferred.

It is advantageous if the channels in a first subregion of an inner space of the first housing are formed between the first housing and the at least one second housing. An improved heat transfer between the first housing and the at least one second housing may thereby be achieved. A heat transfer between the first medium flow and the heat transfer apparatus is thereby improved.

In particular, the channels in a second subregion of an inner space of the first housing are formed between a plurality of second housings. An improved heat transfer between a plurality of second housings is thereby achieved. A heat transfer between the first medium flow and the heat transfer apparatus may thereby be further improved.

In particular, a plurality of channels separated in a fluid-tight manner is formed in an inner space of the third housing. A great amount of heat may thereby be transferred from the second medium flow to the third housing.

It is favorable if at least one entry port and at least one outlet port for the first medium flow are associated with the first housing. As a result, the first medium flow may be guided through the first housing and, for example, the at least one second housing in the first housing may be flowed around with the first medium flow.

In particular, at least one entry port and at least one exit port for the second medium flow are associated with the third housing. The third housing may thereby be flowed through with the second medium flow.

For example, ports for the first medium flow and ports for the second medium flow are arranged on sides of the first housing located transverse to each other. The expenditure for distribution apparatuses may thereby be minimized. Further, the first medium flow and the second medium flow may be separated in a simple manner, such that they do not come into contact with each other.

It is further favorable if a flow direction of the first flow medium is oriented transversely to a flow direction of the second medium flow. The heat transfer apparatus may thereby be flowed through in a simple manner with the first medium flow and the second medium flow. The first medium flow and the second medium flow may then flow from different directions into and out of the heat transfer apparatus, respectively.

In particular, a flow direction of the first medium flow is oriented parallel to a flow direction of the second medium flow. The heat transfer apparatus may thereby be flowed through in a simple manner by the first medium flow and the second medium flow. The first medium flow and the second medium flow may then flow from the same directions into the heat transfer apparatus and out of the same, respectively.

In particular, a medium flow of the first medium flow and the second medium flow is a cold medium flow and the other medium flow a hot medium flow. As a result, a heat flow between the at least one second housing and the third housing may be achieved, which flow may be used, for example, by a thermoelectric module device.

It is favorable if the third housing has at least one planar walling region facing toward the at least one second housing. A thermoelectric module and/or a heat storage element may lie with a planar side against the planar walling region. A uniform contact pressure over the entire surface may thereby be achieved. In particular thermomechanical tensions may thereby be minimized and a heat conduction between the components improved.

For the same reason, it is favorable if the at least one second housing has at least one planar walling region facing toward the third housing. The thermoelectric module and/or the heat storage element may lie with a planar side against this planar walling region.

In particular, at least one heat storage element of the heat storage device is placed against the planar walling region or against the planar walling regions. A thermal mechanical contact between the at least one heat storage element with said planar walling regions may thereby be produced in a simple manner. The at least one heat storage element may thereby be clamped in a simple manner between the third housing and the at least one second housing with a contact pressure over the entire surface. This, in turn, reduces the thermomechanical tensions and improves the thermal conductivity.

In particular, at least one heat storage element of the heat storage device is with a first side in thermal contact with the at least one second housing and with a second side in thermal contact with the third housing. A thermal contact between the heat storage element and the first medium flow as well as the second medium flow may thereby be produced in a simple manner. Heat may thereby be supplied to the heat storage device in a simple manner and be removed from the heat storage device in a simple manner.

It is then favorable if in each case at least one heat storage element is positioned on opposite sides of the third housing, and in particular if the third housing is positioned between opposite heat storage elements, and in particular if the opposite heat storage elements form spacers for the positioning of the third housing in the at least one second housing. The heat transfer apparatus may thus be configured in a simple manner.

In particular, the at least one heat storage element comprises a housing, wherein the heat-conducting medium is arranged in an inner space of the housing. As a result, the heat storage element and the heat storage device, respectively, may be simply and compactly realized.

It is favorable if the heat-conducting medium of the heat storage device is positioned in an inner space formed between the at least one second housing and the third housing. A thermal contact between the at least one second housing and the third housing may thereby be produced in a simple manner. The heat transfer apparatus is thereby configured compactly.

It is then favorable if the conductive medium completely occupies the inner space. The third housing may then, e.g., be held within the second housing by the heat-conducting medium. Furthermore, the thermal contact between the heat-conducting medium and the second housing as well as the third housing may thereby be further improved.

In an advantageous embodiment, the heat transfer apparatus has a thermoelectric module device which is in thermal contact with the heat storage device and the at least one second housing. A heat flow present due to a temperature difference of the first medium flow and the second medium flow may be used by the thermoelectric module device for directly generating electrical energy as a result of the Seebeck effect.

In particular, the thermoelectric module device comprises at least one thermoelectric module, wherein the at least one thermoelectric module is with a first side in thermal contact with the at least one second housing and with a second side in thermal contact with the heat storage device. The thermoelectric module device may thereby be integrated in the heat transfer apparatus in a simple manner. The thermoelectric module is then in an indirect thermal contact with the second medium flow by way of the heat storage device. Fluctuations over time in a temperature delivery by the second medium flow, for example, may in this way be at least largely compensated by the heat storage device. In this case, the temperature fluctuations and fluctuation in a heat flow at the thermoelectric module device are thereby reduced. The efficiency of the thermoelectric module device is thereby increased.

It is favorable if in each case a thermoelectric module of the thermoelectric module device is positioned on opposite sides of the at least one second housing. The heat storage device and the third housing are then positioned in the second housing between opposite thermoelectric modules and in particular clamped between the same. The opposite thermoelectric modules then form spacers for the positioning of the heat storage apparatus and the third housing in the second housing.

For the same reason, it is favorable if the third housing is positioned between opposite combinations of thermoelectric modules and heat storage elements of the heat storage device, and in particular if the opposite combinations form spacers for the positioning of the third housing in the at least one second housing. The third housing is then positioned in the second housing between opposite thermoelectric modules and heat storage elements and in particular is clamped between the same. The opposite thermoelectric modules and heat storage elements then form spacers for the positioning of the third housing in the second housing.

In particular, arranged between the at least one second housing and the third housing is a fourth housing which is in thermal contact with the heat storage device of the thermoelectric module device, wherein the third housing is arranged within the fourth housing, the heat storage device is arranged between the third housing and the fourth housing, and wherein the thermoelectric module device is arranged between the fourth housing and the at least one second housing. As a result of the arrangement of the heat storage device between the third housing and the fourth housing, a heat transfer between the second medium flow and the heat storage device may be further improved. The heat-conducting medium of the heat storage device may then, for example, be arranged in such a way that it completely surrounds the third housing. The heat transfer apparatus may thereby be simply and compactly configured and the heat conduction between the components improved.

It is favorable if the heat-conducting medium of the heat storage device is positioned in an inner space formed between the third housing and the fourth housing. The heat-conducting medium of the heat storage device may thereby be integrated into the heat transfer apparatus in a simple manner. The heat transfer apparatus may thereby be simply and compactly configured.

It is then favorable if the heat-conducting medium completely occupies the inner space between the third housing and the fourth housing. The third housing may then, for example, be held within the fourth housing by the heat-conducting medium. Furthermore, the heat transfer between the second medium flow and the heat storage device is thereby improved.

In particular, the fourth housing is positioned in the at least one second housing between the opposite thermoelectric modules of the thermoelectric module device, and in particular the opposite thermoelectric modules form spacers for the positioning of the fourth housing in the second housing. As a result, the thermoelectric modules function as a kind of spacer for the fourth housing and the fourth housing may be clamped between the thermoelectric modules. In turn, a contact force over the entire surface against the thermoelectric modules may thereby be achieved. The thermal contact between the components may hereby be further improved.

It is favorable if the fourth housing has at least one planar walling region facing toward the at least one second housing. A thermoelectric module may lie with a planar side against the planar walling region. A uniform contact pressure over the entire surface may thereby be achieved. In particular thermomechanical tensions may thereby be minimized. The thermal contact between the components is hereby further improved.

For the same reason, it is favorable if the at least one second housing has at least one planar walling region facing toward the fourth housing. The thermoelectric module may lie with a planar side against this planar walling region.

In particular, the thermoelectric module device is placed against the planar walling region or against the planar walling regions of the at least one second housing and/or against the planar walling region or the planar walling regions of the fourth housing. A thermoelectric module may thereby be clamped between the second housing and the fourth housing in a simple manner. The thermoelectric module may then be clamped with a contact pressure over the entire surface, which in turn reduces the thermomechanical tensions. Furthermore, the fourth housing may thereby also be clamped between opposite thermoelectric modules in the second housing.

It is favorable if the fourth housing has at least one planar walling region facing toward the third housing. Components like, for example, a thermoelectric module or a heat storage element may thereby be arranged between the fourth housing and the third housing in a simple manner. The third housing may then, for example, be held within the fourth housing by the thermoelectric modules and/or the heat storage elements.

It is favorable if a melting temperature of the heat-conducting medium corresponds to an operating temperature and in particular a maximum operating temperature of the thermoelectric module device. As a result, for example in the event of a too hot second medium flow, an overheating of thermoelectric modules of the thermoelectric module device may be avoided. The efficiency of the thermoelectric module device may thereby be further increased.

### BRIEF DESCRIPTION OF THE DRAWINGS

The subsequent description of preferred embodiments serves in conjunction with the drawings for further explanation of the invention.

In the drawings:

FIG. 1 shows a schematic sectional view of a first embodiment of a heat transfer apparatus;

FIG. 2 shows a schematic sectional view of a second embodiment of a heat transfer apparatus with thermoelectric modules;

FIG. 3 shows a schematic sectional view of an embodiment of a thermoelectric module;

FIG. 4 shows a schematic sectional view of a third embodiment of a heat transfer apparatus;

FIG. 5 shows a schematic sectional view of a fourth embodiment of a heat transfer apparatus with thermoelectric modules;

FIG. 6 shows a schematic sectional view of a fifth embodiment of a heat transfer apparatus;

FIG. 7 shows a schematic sectional view of a sixth embodiment of a heat transfer apparatus;

FIG. 8 shows a schematic sectional view of a seventh embodiment of a heat transfer apparatus with thermoelectric modules; and

FIG. 9 shows a schematic sectional view of an eighth embodiment of a heat transfer apparatus with thermoelectric modules.

### DETAILED DESCRIPTION OF THE INVENTION

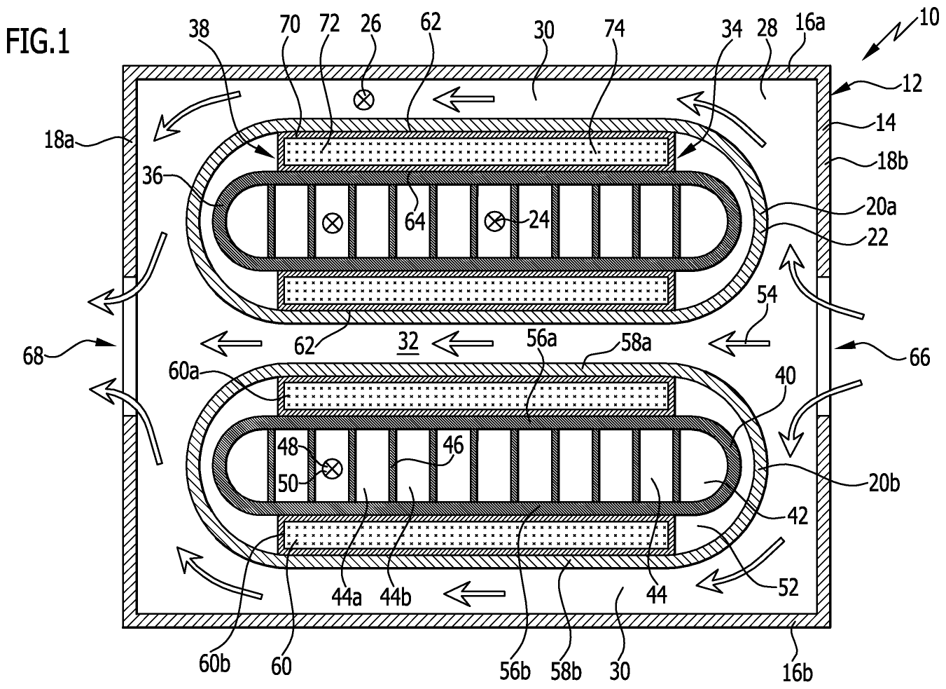

An embodiment of a thermoelectric heat transfer apparatus, which is shown schematically in FIG. 1 in a sectional representation and is designated there by 10, comprises a first housing 12.

The first housing 12 is an exterior housing. It is formed by means of a pipe and, e.g., a box pipe. In one embodiment, it has a walling 14 with opposite walls 16a, 16b oriented in parallel to each other and opposite walls 18a, 18b oriented in parallel to each other. The walls 18a, 18b are transverse and in particular perpendicular to the walls 16a, 16b. The wall 18a is connected to the walls 16a and 16b. The wall 18b is connected to the walls 16a and 16b. The walling 14 forms with its walls 16a, 16b, 18a, 18b a circumferential housing part of the first housing 12. The first housing 12 is closed on its face sides by opposite face walls.

Arranged in the first housing 12 is a plurality of second housings 20 which in particular are configured as capsule pipes. In the embodiment shown, two second housings 20 (housing 20a, housing 20b) are arranged in the first housing 12. It is also possible in principle for more than two second housings 20 to be arranged in the first housing 12 or for only one single second housing 20 to be arranged in the first housing 12.

The first housing 12 is closed in a fluid-tight manner (except for ports mentioned in more detail below).

Each second housing 20 comprises a walling 22. The walling 22 is configured to be circumferentially closed. The walling is oriented with an axis 24 in parallel to a longitudinal direction 26 of the first housing 12. The longitudinal direction 26 is hereby in particular parallel to the walls 16a, 16b, 18a, 18b of the walling 14 and is transverse and in particular perpendicular to the face walls of the first housing 12.

The wallings 22 of the respective second housing 20 are at a distance from the walling 14. Furthermore, wallings 22 of different second housings 20a, 20b are at a distance from each other.

An inner space 28 is formed in the first housing 12. The inner space 28 has a plurality of subregions 30 which are located between the respective second housing 20a, 20b and the walling 14. The inner space 28 has one or a plurality of second subregions 32 between adjacent second housings 20a, 20b.

The respective second housing 20 is closed in a fluid-tight manner. A combination 34 of a third housing 36 and a heat storage device 38 is arranged in the respective second housing 20.

The third housing 36 is configured to be fluid-tight (except for ports described below). The third housing 36 has a circumferential walling 40 with an axis, wherein the axis is at least approximately coaxial to the axis 24.

The third housing 36 has an inner space 42 which is subdivided into a plurality of spaced apart channels 44, wherein all or a subset of the channels are aligned parallel to each other and in particular are oriented in the longitudinal direction 26. Adjacent channels 44a, 44b are separated from each other are by a common fluid-tight walling 46.

Every third housing 36 has one or a plurality of entry ports and one or a plurality of exit ports which are formed on the face walls of the first housing 12. A flow of a medium, which in the following is referred to as second medium flow 48, may be coupled into the respective third housing 36 by way of the entry ports. The second medium flow 48 may be decoupled by way of the exit ports.

The second medium flow 48 flows through the third housing 36 in a flow direction 50. The flow direction 50 is at least approximately parallel to the longitudinal direction 26.

An inner space 52 is formed between the walling 40 of the third housing 36 and the walling 22 of the second housing 20. Said inner space 52 is completely encapsulated in a fluid-tight manner with respect to the inner space 28 and the inner space 42.

A further flow of a medium, which is referred to in the following as first medium flow 54, flows in the inner space 28. The second medium 48 flows in the inner space 42. Neither the first medium flow 54 nor the second medium flow 48 are able to enter the inner space 52.

Furthermore, the second housings 20 are closed such that the first medium flow 54 is not able to enter the inner space 42 of the third housing 36.

Furthermore, the third housing 36 is closed to the second housing 20 in such a way that the second medium flow 48 is not able to enter the inner space 28.

The walling 40 of the third housing 36 has a first walling region 56a and a second walling region 56b opposite the first walling region 56a. The walling regions 56a and 56b are aligned in parallel to each other. Formed between them are the channels 44 which have the same height (a height direction is the distance direction between the first walling region 56a and the second walling region 56b). The first walling region 56a and the second walling region 56b are preferably at least approximately parallel to the walls 16a, 16b of the first housing 12.

The first walling region 56a and the second walling region 56b are formed planar facing toward the second housing 20.

The walling 22 of the second housing 20 has a first walling region 58a and a second walling region 58b opposite the first walling region 58a. The first walling region 58a is adjacent to the first walling region 56a and the second walling region 58b is adjacent to the second walling region 56b.

The first walling region 58a and the second walling region 58b are aligned at least approximately parallel to each other. They are preferably parallel to the walls 16a, 16b and parallel to the walling regions 56a and 56b. A distance between the first walling region 56a and the first walling region 58a as well as a distance between the second walling region 56b and the second walling region 58b is at least approximately constant.

The first walling region 58a and the second walling region 58b are formed planar facing toward the third housing 36.

The heat storage device 38 comprises a plurality of heat storage elements 60. In each case one heat storage element 60 is positioned between the first walling region 56a of the third housing 36 and the first walling region 58a of the second housing 20 as well as between the second walling region 56b of the third housing 36 and the second walling region 58b of the second housing 20.

Heat storage elements 60a, 60b are located opposite each other between the third housing 36 and the second housing 20, wherein the third housing 36 is located between such a pair of heat storage elements 60a, 60b. Such heat storage elements 60a, 60b act as spacers for the positioning of the third housing 36 in the second housing 20.

The heat storage elements 60 are arranged in the inner space 52. They are each with a first side 62 in thermal contact with the second housing 20 and with a second side 64 in thermal contact with the third housing 36. The respective heat storage elements 60 lie with the first side 62 against the walling 22 of the second housing 20 and with the second side 64 against the walling 40 of the third housing 36. In this way, a thermal contact is produced between the heat storage element 60, the second housing 20, and the third housing 36.

In this context, reference is made with respect to the production and design of the first housing 12, the second housing 20, and the third housing 36, as well as with regard to further details of the production of a thermal contact between the individual components, to DE 20 2010 018 101 U1 (filing date: 19 Oct. 2010) of the same applicant. Express reference is made thereto in its entirety.

An entry port 66 and an exit port 68 for the first medium flow 54 are arranged on the first housing 12. Correspondingly, the first medium may be coupled in by the entry port 66 and be discharged by the exit port 68.

The entry port 66 is arranged on the wall 18a and the exit port 68 on the wall 18b. The entry port 66 and the exit port 68 are located transverse to the entry port and the exit port of the third housing 36. The first medium flow 54 is thereby guidable in the flow direction transversely to the flow direction of the second medium flow 48.

The second housings 20 are positioned in the first housing 12 at a distance from the walling 14. A first medium flow 54 coupled in by way of the entry port 66 and first medium flow 54 decoupled by way of the exit port 68 may thereby flow around the second housing 22.

A heat storage element 60 comprises a housing 70. An inner space 72 is formed in the housing 70.

A heat-conducting medium 74 is arranged in the inner space 72. The heat-conducting medium 74 is in thermal contact with the housing 70. The housing 70 is in thermal contact with the second housing 20 and the third housing 36 by way of the first side 62 and the second side 64.

The heat-conducting medium 74 has in particular a metallic thermal conductivity. The heat-conducting medium 74 is produced in particular of a phase change medium. As a result of the phase change medium, a heat flow transmitted by way of the heat transfer apparatus 10 is made uniform over time.

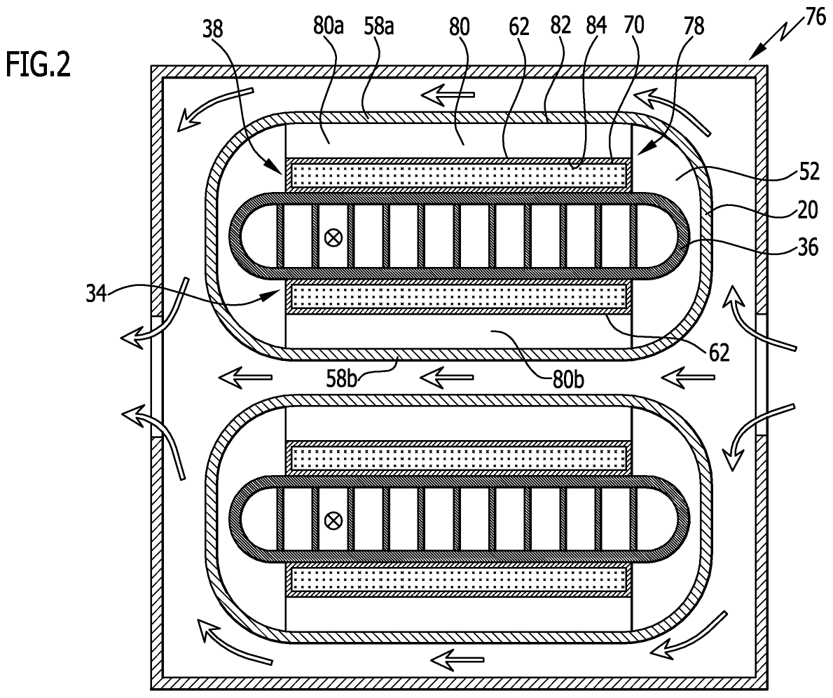

In a second embodiment of a heat transfer apparatus, which is shown in FIG. 2 and is designated there as 76, the heat transfer apparatus comprises a thermoelectric module device 78. Otherwise, the structure is basically the same as in the heat transfer apparatus 10. The same reference numerals are used for the same elements. The description of the previous embodiment shall continue to apply to these elements.

The thermoelectric module device 78 comprises a plurality of thermoelectric modules 80. The combination 34 of the third housing 36 and the heat storage device 38 is positioned between the thermoelectric modules 80 of the thermoelectric module device 78.

In each case one thermoelectric module 80 is positioned between the first walling region 58a of the second housing 20 and the first side 62 of the heat storage element 60. Likewise, in each case one thermoelectric module 80 is positioned between the second walling region 58a of the second housing 20 and the first side 62 of the heat storage element 60. A plurality of thermoelectric modules 80 may hereby be arranged in the longitudinal direction 26 on the heat storage device 38.

Thermoelectric modules 80a, 80b are located opposite each other between the third housing 36 and the second housing 20, wherein the combination 34 is located between such a pair of thermoelectric modules 80a, 80b.

The thermoelectric modules 80 are arranged in the inner space 52. They are each with a first side 82 in thermal contact with the second housing 20 and with a second side 84 in thermal contact with the heat storage device 38. In particular, the respective thermoelectric modules 80 lie with the first side 82 against the walling 22 of the second housing 20 and with the second side 84 against the first side 62 of the heat storage elements 60. In this way, a thermal contact between the heat storage device 38 and the second housing 20 is produced by way of the thermoelectric module device 78.

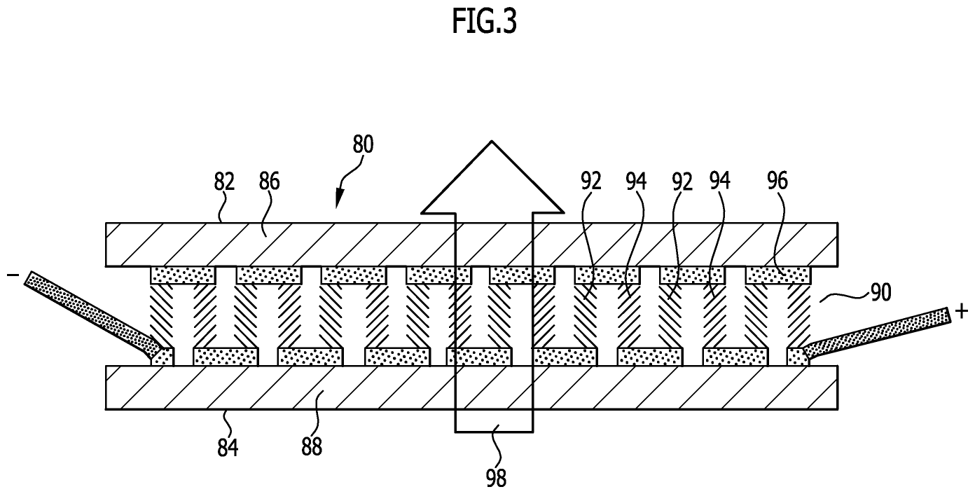

A thermoelectric module 80, which is shown in FIG. 3, comprises in one embodiment a first housing element 86 and a second housing element 88 opposite the first housing element 86. The first side 82 is formed on the first housing element 86 and the second side 84 is formed on the second housing element 88. The first housing element 86 and the second housing element 88 are formed in particular of a material with metallic heat conductivity.

The first side 82 and the second side 84 are in particular of planar configuration. This enables an optimized abutment of the first side 82 and the second side 84 against the first walling region 58a and against the second walling region 58b, respectively, of the second housing 20 and against the first side 62 of the heat storage element 60.

The first housing element 86 and the second housing element 88 are produced of an electrically insulating material. In particular, an electrical insulation is arranged facing toward an inner space 90 between the first housing element 86 and the second housing element 88.

For example, N-type conductors 92 and P-type conductors 94 are positioned in the inner space 90, wherein adjacent N-type conductors 92 and P-type conductors 94 are connected to each other by way of an electrically conductive bridge 96 (for example of a metallic material).

If, for example, the first side 82 is a cold side and the second side 84 is a hot side, then a heat flow 98 arises at the thermoelectric module 80 between the first housing element 86 and the second housing element 88. A useable electrical current may be generated therefrom by way of the Seebeck effect.

The exhaust gas heat from a combustion engine, for example, in which the exhaust gas is the second medium flow 48, may be used by way of the thermoelectric modules 80. The waste heat may in this way be directly converted into usable electrical energy.

The heat transfer apparatus 76 functions as follows:

In one embodiment, the second medium flow 48 is a hot medium flow and the first medium flow 54 is a cold medium flow.

For example, the second medium flow 48 is an exhaust gas flow of a combustion engine.

The second medium flow 48 is guided by the third housing 36. The heat storage device 38 is in direct thermal contact with the third housings 36. The heat storage device 38 is also in direct thermal contact with the thermoelectric module device 78. The second sides 84 of the thermoelectric module 80 are thereby heated.

The first medium flow 54 which is a cold medium flow is guided in the first housing 12. A flow direction of the cold medium flow is hereby transverse and in particular perpendicular to the flow direction 50 of the second medium flow 48.

The second housings 20 are flowed around in the first housing 12 by the first medium flow 54. The first side 82 of the thermoelectric modules 80 is in thermal contact with the second housing 20. The first side 82 is thereby cooled. The first side 82 is a cold side. The heat flow 98 may thereby form between the second side 84 and the first side 82 of each thermoelectric module 80. The thermal energy may thereby be directly converted into usable electrical energy.

The second medium flow 48 is, e.g., an exhaust gas flow of a combustion engine. In this case, the second medium flow is subject to temperature fluctuations over time. The heat flow 98 at the thermoelectric modules 80 is hereby increased or reduced as a function of time.

The optimal efficiency of the thermoelectric modules 80, however, is achieved by the construction thereof only in that case that the heat flow 98 is within a certain value range. In the case of a too high or too low heat flow 98, the efficiency of the thermoelectric modules 80 and the thermoelectric module device 78 is reduced.

Fluctuations in the heat flow 98 at the thermoelectric modules 80 are reduced by the heat storage device 38. For this purpose, the heat storage device 38 comprises the heat-conducting medium 74 which in particular is a phase change medium. The phase change medium may store heat in times of high heat emission by the second medium flow 48 and release the stored heat in times of low heat emission by the second medium flow 48. In the case of a temperature of the second medium flow 48 fluctuating over time, the efficiency of the thermoelectric module device 78 is hereby significantly increased.

Furthermore, a maximum operating temperature of the thermoelectric modules 80 may be exceeded in the case of a too high heat flow 98 which, for example, is caused by a second medium flow 48 that is too hot. The thermoelectric modules 80 may hereby overheat. As a result of the buffer effect of the heat storage device 38, temperature exceedances of that kind may be avoided at least within a certain period of time.

In one embodiment, an underpressure is present in the inner space 42 relative to the inner spaces 28 and 52. The components of the heat storage device 38 and the thermoelectric module device 78 are thereby pressed against the second housing 20 and the third housing 36. This results in an areal mechanical contact between the components. A very good thermal contact between the components is thus ensured.

Due to the structure of the heat transfer apparatus 76, a thermoelectric module device may be realized with little complexity. No bracing elements like brackets or the like need to be provided.

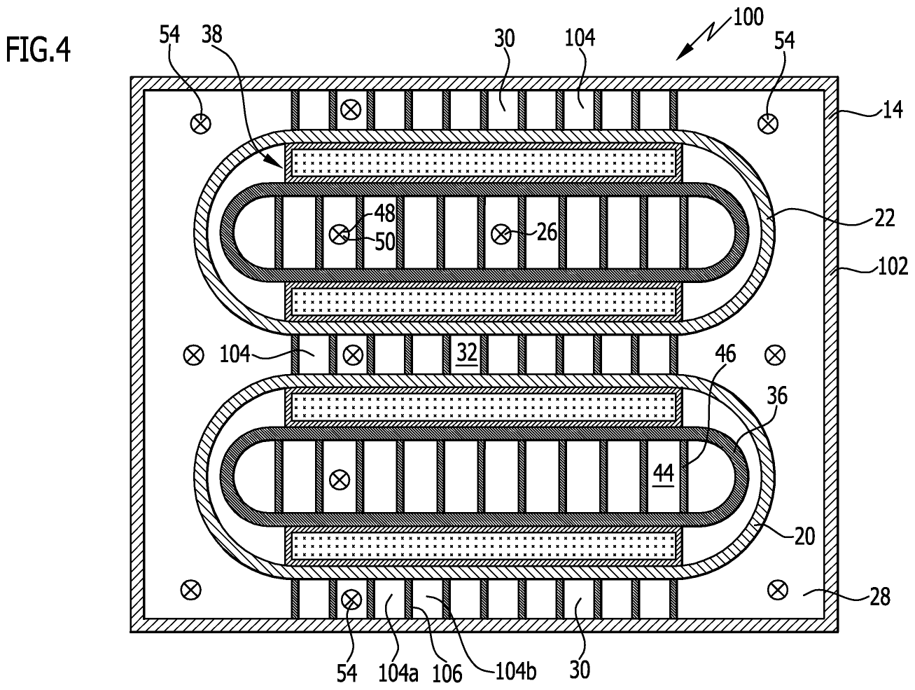

A third embodiment of a heat transfer apparatus is shown in FIG. 4 and designated there by 100. In this embodiment, provision is made for the flow direction of the first medium flow 54 to be at least approximately parallel to the flow direction 50 of the second medium flow 48.

The heat transfer apparatus 100 comprises a first housing 102 which is configured basically the same as the first housing 12 of the heat transfer apparatus 10. Entry ports and exit ports for the first medium flow 54, however, are, in the case of the first housing 102, arranged on face sides of the first housing 102 analogously to the entry ports and outlet ports for the second medium flow 48. The first medium flow 54 may thereby be coupled in and decoupled in parallel to the flow direction 50 of the second medium flow 48.

In the inner space 28 of the first housing 102, channels 104 are formed in the first subregion 30 and the second subregion 32. All or a subset of the channels 104 are aligned in parallel to each other and in particular oriented in the longitudinal direction 26. In particular, adjacent channels 104a, 104b are separated from each other by a common fluid-tight walling 106.

The wallings 106 of the channels 104 are in particular parallel to the wallings 46 of the channels 44 of the third housing 36.

The channels 104 are flowed through by the first medium flow 54. A heat transfer between the heat transfer apparatus 100 and the first medium flow 54 is improved by the channels 104.

The channels 104 are formed in particular between the walling 14 of the first housing 102 and the walling 22 of the second housing 20. The channels 104 are also formed in particular between the wallings 22 of different second housings 20a, 20b. The heat transfer between the first housing 102 and the second housing 20 is thereby improved. Furthermore, the heat transfer between different second housings 20a, 20b is thereby further improved. In this way, the heat transfer between the second housing 20 and the first medium flow 54 is also further improved.

The heat transfer apparatus 100 otherwise has the same functioning as the heat transfer apparatus 10.

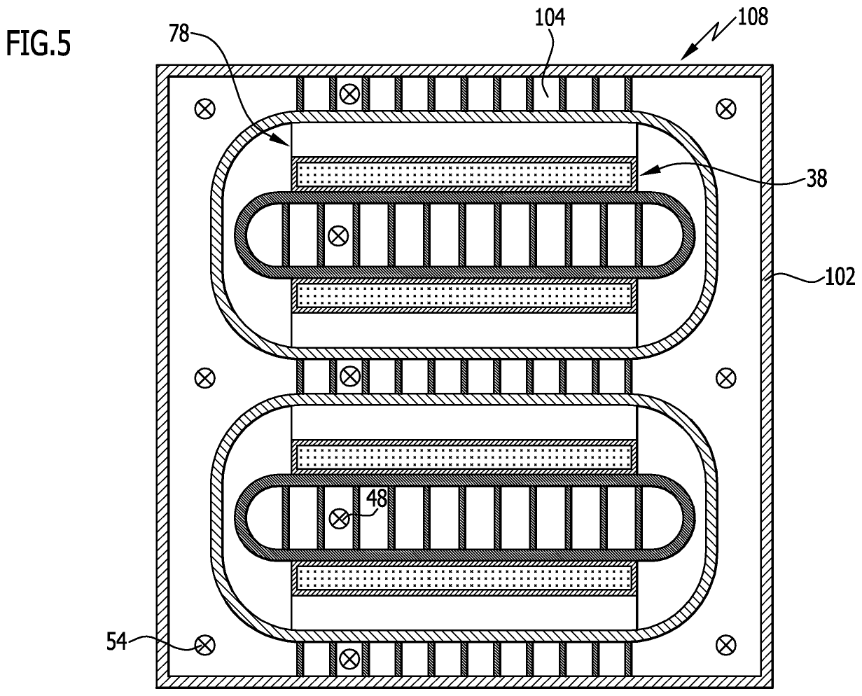

A fourth embodiment of a heat transfer apparatus, which is shown in FIG. 5 and designated there by 108, is constructed basically the same as the heat transfer apparatus 100. However, the heat transfer apparatus 108 additionally comprises the thermoelectric module device 78 described above.

In the heat transfer apparatus 108, a flow direction of the first medium flow 54 is least approximately parallel to the flow direction 50 of the second medium flow 48.

The heat transfer apparatus 108 otherwise functions as described above on the basis of the heat transfer apparatus 76.

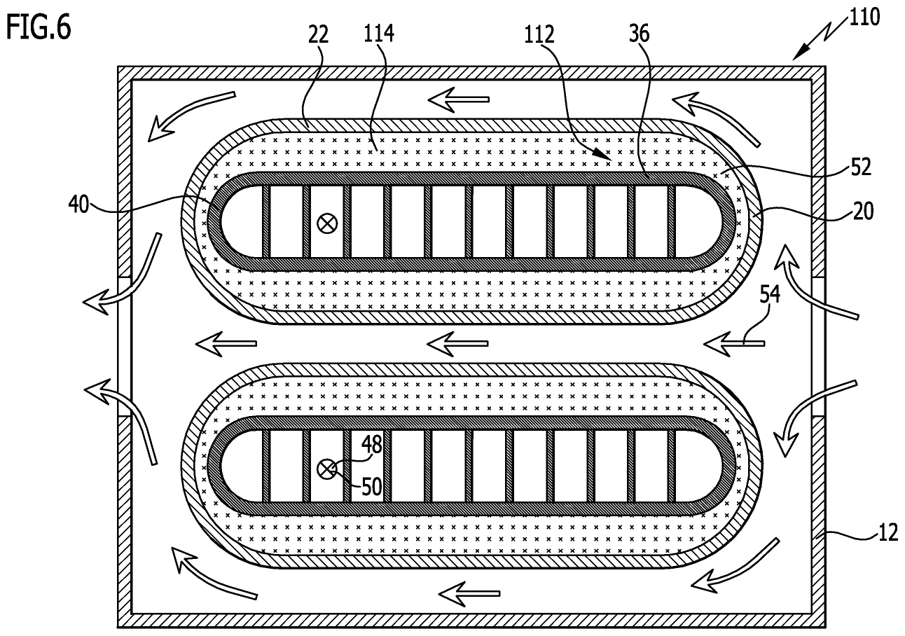

A fifth embodiment of a heat transfer apparatus is shown in FIG. 6 and designated there by 110. The heat transfer apparatus 110 is constructed basically the same as the heat transfer apparatus 10.

The heat transfer apparatus 110 comprises a heat storage device 112 which is arranged in the inner space 52 between the second housing 20 and the third housing 36.

The heat storage device 112 has a heat-conducting medium 114 which occupies the inner space 52, in particular completely. The heat-conducting medium 114 has basically the same properties as the heat-conducting medium 74 of the heat storage device 38. The heat-conducting medium 114 is in particular a phase change medium.

The heat-conducting medium 114 is in thermal contact with the walling 22 of the second housing 20 and with the walling 40 of the third housing 36. As a result, the thermal contact between the heat storage device 112, the second housing 20, and the third housing 36 is improved.

Due to the heat-conducting medium 114 completely occupying the inner space 52, an improved thermal contact between the heat conducting medium 114, the second housing 20, and the third housing 36 may be produced in a simple manner.

In the heat transfer apparatus 110, the flow direction of the first medium flow 54 is transverse and in particular perpendicular to the flow direction 50 of the second medium flow 48.

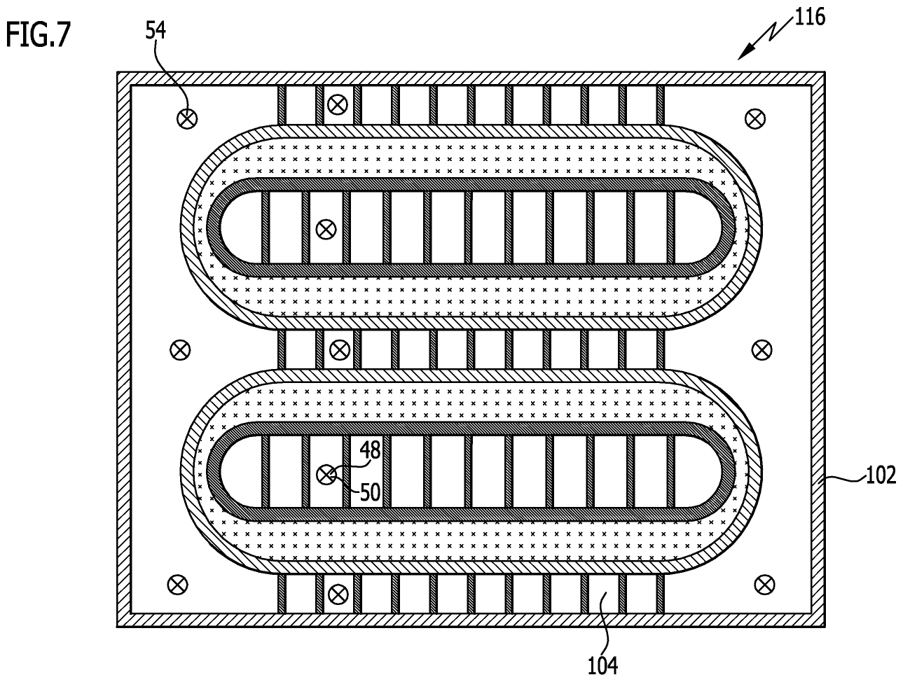

A sixth embodiment of a heat transfer apparatus is shown in FIG. 7 and is designated there by 116.

The heat transfer apparatus 116 is constructed basically the same way as the heat transfer apparatus 110 of the previous embodiment. In the heat transfer apparatus 116, however, a flow direction of the first medium flow 54 is at least approximately parallel to the flow direction 50 of the second medium flow 48. The heat transfer apparatus 116 has channels 104 analogously to the heat transfer apparatus 100.

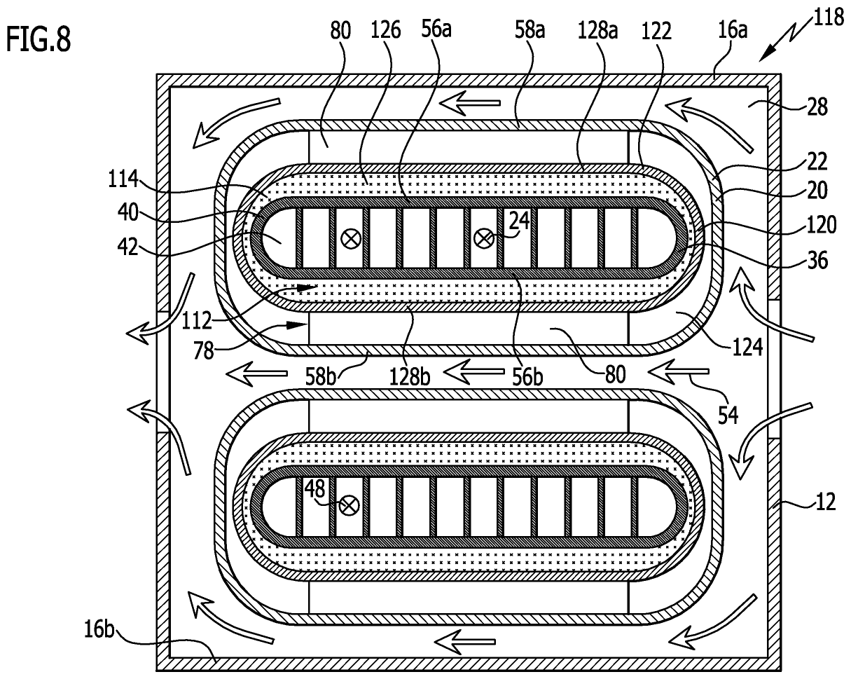

A seventh embodiment of a heat transfer apparatus is shown in FIG. 8 and is designated there by 118.

In the heat transfer apparatus 118, a fourth housing 120 is arranged between the second housing 20 and the third housing 36. The third housing 36 is positioned within the fourth housing 120. The fourth housing 120 is closed in a fluid-tight manner. The fourth housing 120 has a circumferentially closed walling 122 which has an axis that is at least approximately coaxial to the axis 24 of the second housing 20.

An inner space 124 is formed between the walling 22 of the second housing 20 and the walling 122 of the fourth housing 120. An inner space 126 is formed between the walling 122 of the fourth housing 120 and the walling 40 of the third housing 36. This inner space 126 is completely encapsulated in a fluid-tight manner with respect to the inner space 124 and the inner space 42 of the third housing 36. Furthermore, the inner space 124 is completely encapsulated in a fluid-tight manner with respect to the inner space 28 of the first housing 12.

The walling 122 of the fourth housing 120 has a first walling region 128a and a second walling region 128b. The first walling region 128a is adjacent to the first walling region 58a of the second housing 20 and to the first walling region 56a of the third housing 36. The second walling region 128b is adjacent to the second walling region 58b of the second housing 20 and to the second walling region 56b of the third housing 36. The first walling region 128a and the second walling region 128b are aligned at least approximately parallel to each other. They are preferably aligned parallel to the walls 16a, 16b of the first housing 12 and parallel to the walling regions 56a, 56b, 58a, and 58b.

In one embodiment, the first walling region 128a and the second walling region 128b are formed at least approximately planer facing toward the second housing 20 and/or facing toward the third housing 36.

The thermoelectric module device 78 is arranged in the inner space 124. In each case one thermoelectric module 80 is positioned between the first walling region 58a of the second housing 20 and the first walling region 128a of the fourth housing 120 as well as between the second walling region 58b of the second housing 20 and the second walling region 128b of the fourth housing 120.

The heat storage device 112 is arranged in the inner space 126. The heat-conducting medium 114 of the heat storage device 112 occupies the inner space 126, in particular completely. This has already been described above on the basis of the heat transfer apparatus 110.

The heat-conducting medium 114 is in thermal contact with the walling 122 of the fourth housing 120 and with the walling 40 of the third housing 36.

The thermoelectric module device 78 is in thermal contact with the second housing 20. The thermoelectric module device 78 is still in thermal contact with the heat storage device 112 by way of the fourth housing 120. The heat storage device 112 is in thermal contact with the third housing 36.

The first medium flow 54 is located transverse and in particular perpendicular to the second medium flow 48.

In the heat transfer apparatus 118, the thermal contact between the thermoelectric module device 78 and the heat storage device 112 is produced by way of the walling 122 of the fourth housing 120. Otherwise, the heat transfer apparatus 118 functions analogously to the embodiments described above.

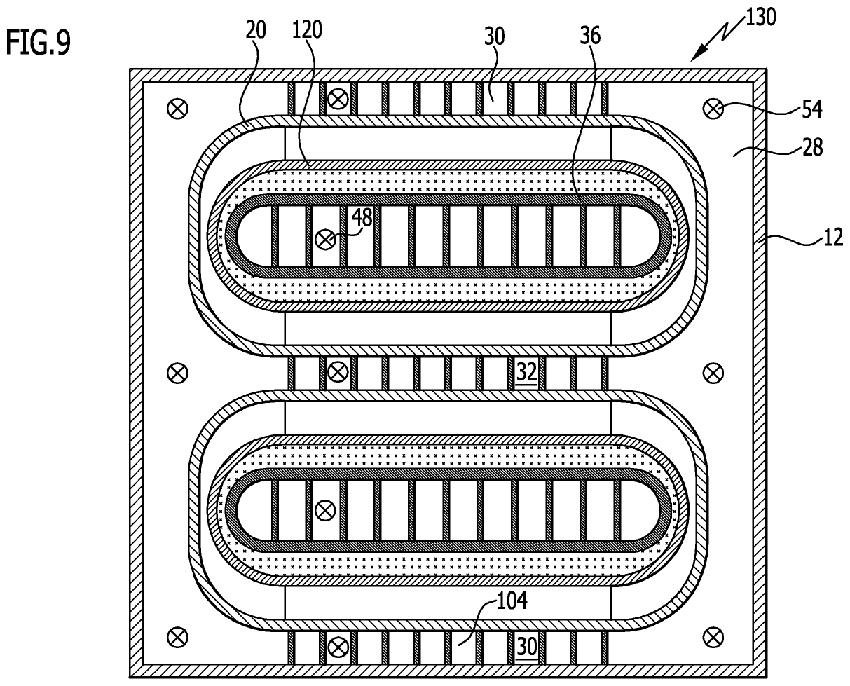

An eighth embodiment of a heat transfer apparatus is shown in FIG. 9 and designated there by 130.

In the heat transfer apparatus 130, the first medium flow 54 is at least approximately parallel to the second medium flow 48.

Channels 104 are formed in the first subregion 30 and the second subregion 32 of the inner space 38 of the first housing 12. The formation of the channels 104 has already been explained above in conjunction with the heat transfer apparatus 100.

The functioning of the heat transfer apparatus 130 is analogous to the embodiments described above.

### REFERENCE NUMERAL LIST

10 heat transfer apparatus
12 first housing
14 walling
16a, 16b walls
18a, 18b walls
20 second housing
20a, 20b second housing
22 walling
24 axis
26 longitudinal direction
28 inner space
30 first subregion
32 second subregion
34 combination
36 third housing
38 heat storage device
40 walling
42 inner space
44 channels
44a, 44b channel
46 walling
48 second medium flow
50 flow direction
52 inner space
54 first medium flow
56a first walling region
56b second walling region
58a first walling region
58b second walling region
60 heat storage element
60a, 60b heat storage element
62 first side
64 second side
66 entry port
68 exit port
70 housing
72 inner space
74 heat-conducting medium
76 heat transfer apparatus
78 thermoelectric module device
80 thermoelectric module
80a, 80b thermoelectric module
82 first side
84 second side
86 first housing element
88 second housing element
90 inner space
92 N-type conductor
94 P-type conductor
96 bridge
98 heat flow
100 heat transfer apparatus
102 first housing
104 channels
104a, 104b channel
106 walling
108 heat transfer apparatus
110 heat transfer apparatus
112 heat storage device
114 heat-conducting medium
116 heat transfer apparatus
118 heat transfer apparatus
120 fourth housing
122 walling
124 inner space
126 inner space
128a first walling region
128b second walling region
130 heat transfer apparatus

What is claimed is:

1. Heat transfer apparatus, comprising:
a fluid-tight first housing;
at least one fluid-tight second housing;
a fluid-tight third housing; and
a heat storage device with a heat-conducting medium;
wherein the at least one second housing is arranged in the first housing;
wherein the third housing is arranged in the at least one second housing;
wherein a first medium flow is guided between the first housing and the at least one second housing;
wherein a second medium flow is guided in the third housing;
wherein the heat storage device is arranged between the at least one second housing and the third housing; and
wherein the heat storage device is in thermal contact with the at least one second housing and the third housing.

2. Heat transfer apparatus in accordance with claim 1, wherein the heat-conducting medium is or comprises a phase change medium.

3. Heat transfer apparatus in accordance with claim 1, wherein a plurality of parallel channels separated in a fluid-tight manner is formed in the first housing.

4. Heat transfer apparatus in accordance with claim 3, wherein the channels in a first subregion of an inner space of the first housing are formed between the first housing and the at least one second housing.

5. Heat transfer apparatus in accordance with claim 3, wherein the channels in a second subregion of an inner space of the first housing are formed between a plurality of second housings.

6. Heat transfer apparatus in accordance with claim 1, wherein a plurality of channels separated in a fluid-tight manner is formed in an inner space of the third housing.

7. Heat transfer apparatus in accordance with claim 1, wherein at least one entry port and at least one exit port for the first medium flow are associated with the first housing.

8. Heat transfer apparatus in accordance with claim 1, wherein at least one entry port and at least one exit port for the second medium flow are associated with the third housing.

9. Heat transfer apparatus in accordance with claim 1, wherein ports for the first medium flow and ports for the second medium flow are arranged on sides of the first housing located transverse to each other.

10. Heat transfer apparatus in accordance with claim 1, wherein a flow direction of the first medium flow is oriented transversely to a flow direction of the second medium flow.

11. Heat transfer apparatus in accordance with claim 1, wherein a flow direction of the first medium flow is oriented parallel to a flow direction of the second medium flow.

12. Heat transfer apparatus in accordance with claim 1, wherein a medium flow of the first medium flow and the second medium flow is a cold medium flow and the other medium flow is a hot medium flow.

13. Heat transfer apparatus in accordance with claim 1, wherein the third housing has at least one planar walling region facing toward the at least one second housing.

14. Heat transfer apparatus in accordance with claim 1, wherein the at least one second housing has at least one planar walling region facing toward the third housing.

15. Heat transfer apparatus in accordance with claim 1, wherein at least one heat storage element of the heat storage device is placed against a planar walling region or against planar walling regions of at least one of the third housing or the at least one second housing.

16. Heat transfer apparatus in accordance with claim 1, wherein at least one heat storage element of the heat storage device is with a first side in thermal contact with the at least one second housing and with a second side in thermal contact with the third housing.

17. Heat transfer apparatus in accordance with claim 16, wherein in each case at least one heat storage element is positioned on opposite sides of the third housing, and in particular in that the third housing is positioned between opposite heat storage elements, and wherein the opposite heat storage elements form spacers for the positioning of the third housing in the at least one second housing.

18. Heat transfer apparatus in accordance with claim 16, wherein the at least one heat storage element comprises a housing, and wherein the heat-conducting medium is arranged in an inner space of the housing.

19. Heat transfer apparatus in accordance with claim 1, wherein the heat-conducting medium of the heat storage device is positioned in an inner space formed between the at least one second housing and the third housing.

20. Heat transfer apparatus in accordance with claim 19, wherein the heat-conducting medium completely occupies the inner space between the at least one second housing and the third housing.

21. Heat transfer apparatus in accordance with claim 1, wherein the heat transfer apparatus comprises a thermoelectric module device which is in thermal contact with the heat storage device and the at least one second housing.

22. Heat transfer apparatus in accordance with claim 21, wherein the thermoelectric module device comprises at least one thermoelectric module, and wherein the at least one thermoelectric module is with a first side in thermal contact with the at least one second housing and with a second side in thermal contact with the heat storage device.

23. Heat transfer apparatus in accordance with claim 22, wherein in each case at least one thermoelectric module of the thermoelectric module device is positioned on opposite sides of the at least one second housing.

24. Heat transfer apparatus in accordance with claim 22, wherein the third housing is positioned between opposite combinations of thermoelectric modules and heat storage elements of the heat storage device, and wherein opposite combinations form spacers for the positioning of the third housing in the at least one second housing.

25. Heat transfer apparatus in accordance with claim 21, wherein arranged between the at least one second housing and the third housing is a fourth housing which is in thermal contact with the heat storage device and the thermoelectric module device, wherein the third housing is arranged within the fourth housing, wherein the heat storage device is arranged between the third housing and the fourth housing, and wherein the thermoelectric module device is arranged between the fourth housing and the at least one second housing.

26. Heat transfer apparatus in accordance with claim 25, wherein the heat-conducting medium of the heat storage device is positioned in an inner space formed between the third housing and the fourth housing.

27. Heat transfer apparatus in accordance with claim 26, wherein the heat-conducting medium completely occupies the inner space between the third housing and the fourth housing.

28. Heat transfer apparatus in accordance with claim 25, wherein the fourth housing is positioned in the at least one second housing between opposite thermoelectric modules of the thermoelectric module device, and wherein the opposite thermoelectric modules form spacers for the positioning of the fourth housing in the second housing.

29. Heat transfer apparatus in accordance with claim 25, wherein the fourth housing has at least one planar walling region facing toward the at least one second housing.

30. Heat transfer apparatus in accordance with claim 25, wherein the at least one second housing has at least one planar walling region facing toward the fourth housing.

31. Heat transfer apparatus in accordance with claim 25, wherein the thermoelectric module device is placed against a planar walling region or planar walling regions of at least one of the at least one second housing or the fourth housing.

32. Heat transfer apparatus in accordance with claim 25, wherein the fourth housing has at least one planar walling region facing toward the third housing.

33. Heat transfer apparatus in accordance with claim 21, wherein a melting temperature of the heat-conducting medium corresponds to an operating temperature and in particular a maximum operating temperature of the thermoelectric module device.
